(19) United States
(12) Patent Application Publication
(10) Pub. No.: US 2024/0273849 A1
(43) Pub. Date: Aug. 15, 2024

(54) DEFORMATION-BASED GENERATION OF CURVED MESHES

(71) Applicant: Siemens Industry Software Inc., Plano, TX (US)

(72) Inventors: Roman Poya, Cambridge (GB); Jean Cabello, Maineville, OH (US); Glen McCann, Sharonville, OH (US)

(73) Assignee: Siemens Industry Software Inc., Plano, TX (US)

(21) Appl. No.: 18/565,272

(22) PCT Filed: Jun. 16, 2021
(86) PCT No.: PCT/US2021/037619

§ 371 Date: Nov. 29, 2023

(51) Int. Cl. G06T 19/20; G06F 30/12

(52) U.S. Cl. CPC G06T 19/20; G06F 30/12; G06T 2219/2021

(57) ABSTRACT

A computing system may include a linear mesh access engine configured to access a linear mesh and a target geometry as well as curved mesh generation engine configured to construct a curved mesh. Construction of the curved mesh may include projecting the linear mesh on to the target geometry to form a projected mesh, determining deformation patches included in the projected mesh, selecting a cost function to apply to the deformation patches from a set of available cost functions, iteratively adapting the deformation patches based on the selected cost function to obtain adjusted mesh elements, and forming the curved mesh as a combination of the adjusted mesh elements and portions of the projected mesh not determined as part of the deformation patches.

### BACKGROUND

Computer systems can be used to create, use, and manage data for products, items, and other objects. Examples of computer systems include computer-aided design (CAD) systems (which may include computer-aided engineering (CAE) systems), visualization and manufacturing systems, product data management (PDM) systems, product lifecycle management (PLM) systems, and more. These systems may include components that facilitate the design, visualization, and simulated testing of product structures and product manufacture.

### BRIEF DESCRIPTION OF THE DRAWINGS

Certain examples are described in the following detailed description and in reference to the drawings.

FIG. 1 shows an example of a computing system that supports deformation-based generation of curved meshes.

FIG. 2 shows an example generation of a projected mesh and an example determination of a deformed mesh element according to the present disclosure.

FIG. 3 shows an example generation of adjusted mesh elements from deformation patches identified for a projected mesh.

FIG. 4 shows an example of logic that a system may implement to support deformation-based generation of curved meshes.

FIG. 5 shows an example of a computing system that supports deformation-based generation of curved meshes.

### DETAILED DESCRIPTION

With technological advancements in CAD computing systems, the capabilities of CAD-based design, simulation, and processing of CAD models are increasing as well. Complex simulations can be performed to test nearly any aspect, characteristic, or behavior of CAD objects that digitally model physical products. CAE systems may, for example, provide finite element analysis (FEA)-based simulation suites that can implement complex and robust simulation features for a vast variety of tests on nearly any type of product. Example simulation scenarios supported by modern CAE systems range from thermal simulations of gas turbine components, to pressure measurements for composite ply-layup procedures, to complex fluid dynamics simulations, to detailed impact simulations of car parts in vehicular crashes.

Simulation suites typically rely on an underlying mesh to drive simulation capabilities. A mesh may be comprised of mesh elements that together cover the surface (or volume) of a CAD model, forming the mesh. Mesh elements may have various characteristics, shapes, and parameters, with specific mesh element attributes depending on the meshing process used to generate the mesh. For instance, mesh elements can be triangular, quadrilateral, or hexahedral in shape, as but a few examples. Meshes may also come in various types, and a linear mesh may refer to a mesh in which mesh elements are composed of nodes connected through linear edges (also referred to as segments or edge segments). As used herein, a linear mesh may refer to a mesh in which mesh elements of the mesh have linear edges (e.g., linear segments that connect the nodes that form the mesh elements of the linear mesh).

In modern simulation technologies, linear meshes have clear limitations. Linear meshes may behave poorly in complex simulations and can exhibit visual and numerical artifacts, such as bending locking, volumetric locking, and spurious stress oscillations. In general, linear meshes may be incapable of sufficiently accurate simulations unless the linear mesh is sufficiently refined. However, refining linear meshes to a threshold granularity to provide requisite accuracy for FEA simulation can result in excessive use of computational resources and, in certain cases, prohibitively long mesh refinement and simulation times. Furthermore, linear meshes generated from an underlying CAD model having a smooth NURBS description cannot fully or completely represent a curved geometry through piecewise linear segments. Amongst other issues, this lack of exact geometry representation in linear meshes can lead to non-physical stress concentrations around concave areas such as holes and circular inclusions in structural FEA analysis.

Curved meshes, on the other hand, can address many of the issues that afflict linear meshes in FEA simulations, and can potentially do so with a much lower mesh element count (e.g., with coarser mesh elements) and lesser computational resource requirements while providing increased accuracy in representing smooth geometries. As used herein, a curved mesh may refer to a mesh in which mesh elements of the curved mesh are composed of nodes connected, at least in part, through curved edges. Curved meshes (e.g., mesh elements with parabolic edges) may be able to provide more accurate results for a fraction of the computational cost of linear meshes due to a richer underlying representation and ability to accurately capture geometries at a coarser (e.g., larger) mesh element size as compared to linear meshes.

Generation of coarse curved meshes on complex geometries can be a challenging technological problem. Conventional curved mesh generation techniques include ad-hoc approaches, which use simple mesh generation heuristics that can only support limited types of mesh elements and offer no guarantee that the curved mesh generation process can actually complete. Other techniques include a posteriori processing of linear meshes into curved meshes, though such techniques can result in invalid mesh elements with disordered nodes resulting from the curved mesh generation process that are inverted or cause folding in the curved mesh elements. Some techniques to address invalid curved mesh elements resultant from a posteriori processes rely on building a mapping from the isoparametric domain of a curved mesh element to the corresponding CAD description, and using optimization and/or minimization techniques to “untangle” the invalid curved mesh elements. Optimization-based techniques can be computationally expensive, and may require a significant number of optimization iterations that process an entire mesh. Thus, conventional optimization techniques may require processing all of the mesh elements of a curved mesh in order to reach a suitable solution to adequately repair, address, or process invalid curved mesh elements. Such lengthy computational and latency requirements (especially for complex meshes increasingly prevalent today) may render such optimization techniques untenable and impractical in many CAD contexts.

The disclosure herein may provide systems, methods, devices, and logic for deformation-based generation of curved meshes. As described in greater detail, the deformation-based curved mesh generation technology disclosed herein may directly address (e.g., untangle) invalid curved mesh elements of any kind, and thus resolve element-specific limitations of conventional ad-hoc techniques restricted to limited types of mesh elements (e.g., division into linear/planar mesh elements and applying optimization techniques that are limited only to linear meshes). As another feature, the deformation-based curved mesh generation technology of the present disclosure need not process all of the curved mesh elements in generation of curved meshes, and may instead focus processing on determined deformation patches to process and untangle relevant nodes in order to repair invalid curved mesh elements. Such selective processing of determined deformation patches may improve computing performance of CAD systems in contrast to conventional optimization techniques that iterate over entire curved meshes, which may increase processing capability of CAD systems and reduced execution latencies.

As yet another technical feature of the present disclosure, the deformation-based curved mesh generation technology presented herein may utilize curve displacements in mapping linear meshes to curved target geometries and leverage the determined curve displacements as constraints in the processing and repair of invalid curved mesh elements. Through deformation-based techniques that utilize determined curve displacements, the deformation-based curved mesh generation technology of the present disclosure can reduce a number of adaptation iterations required to address invalid curved mesh elements, and significantly so in some cases. Such a reduction may improve the technical capability of CAD computing systems by improving processing speed, performance, and reducing execution times. As yet another feature, the deformation-based curved mesh generation technology may selectively and/or dynamically determine cost functions to apply in adaptation iterations, which can provide increased flexibility and improve performance by filtering cost functions that would result in an unwieldy number of execution iterations or otherwise drag performance. In any such ways, the deformation-based curved mesh generation technology presented herein may provide a robust, flexible, and efficient framework for curved mesh generations of any family of mesh elements.

These and other features of the deformation-based curved mesh generation technology and the technical benefits of the present disclosure are described in greater detail herein.

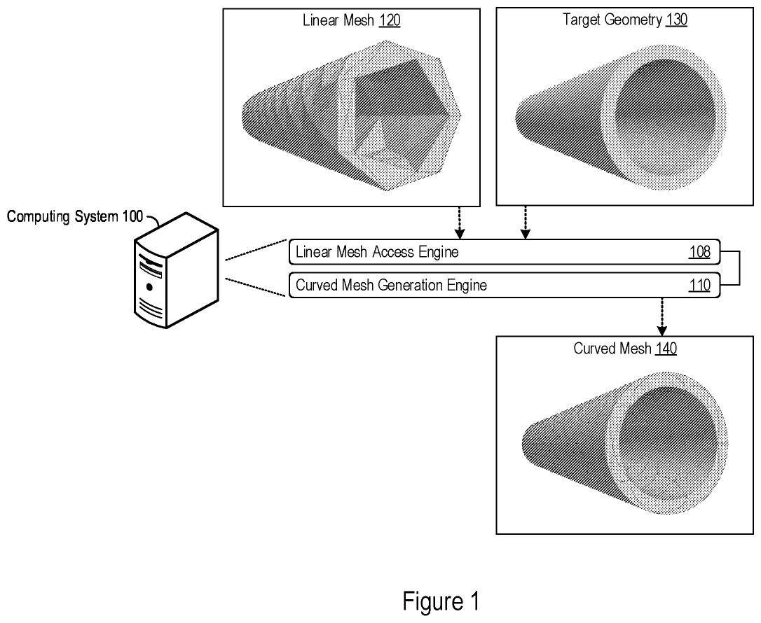

FIG. 1 shows an example of a computing system 100 that supports deformation-based generation of curved meshes. The computing system 100 may take the form of a single or multiple computing devices such as application servers, compute nodes, desktop or laptop computers, smart phones or other mobile devices, tablet devices, embedded controllers, and more. In some implementations, the computing system 100 hosts, supports, executes, or implements a CAD application that provides any combination of mesh generation and processing capabilities.

As an example implementation to support any combination of the deformation-based curved mesh generation features described herein, the computing system 100 shown in FIG. 1 includes a linear mesh access engine 108 and a curved mesh generation engine 110. The computing system 100 may implement the engines 108 and 110 (including components thereof) in various ways, for example as hardware and programming. The programming for the engines 108 and 110 may take the form of processor-executable instructions stored on a non-transitory machine-readable storage medium and the hardware for the engines 108 and 110 may include a processor to execute those instructions. A processor may take the form of single processor or multi-processor systems, and in some examples, the computing system 100 implements multiple engines using the same computing system features or hardware components (e.g., a common processor or a common storage medium).

In operation, the linear mesh access engine 108 may access a linear mesh 120 and a target geometry 130. The linear mesh 120 may be comprised of mesh elements various dimensions, whether 1D, 2D, or 3D, and of any element type, such as beams, triangles, quadrilaterals, tetrahedrons, pyramids, prisms/wedges, hexahedrons, and more. Mesh elements of the linear mesh 120 may be linear mesh elements in that each edge of the mesh elements is a line (e.g. a straight edge). The target geometry 130 may be any geometrical representation of an object, and may take the form of a CAD representation or CAD model (e.g., NURBS or other B-spline representation). The linear mesh access engine 108 may access the linear mesh 120 and the target geometry 130 in various ways, for example through user inputs or selection operations from a CAD application. In some implementations, the linear mesh 120 is generated from the target geometry 130, in which case the linear mesh access engine 108 may itself generate the linear mesh 120 from the target geometry 130, and may do so according to any known linear meshing processes.

In operation, the curved mesh generation engine 110 may construct, from the linear mesh 120, a curved mesh 140 for the target geometry 130. The curved mesh generation engine 110 may do so by projecting the linear mesh 120 on to the target geometry 130 to form a projected mesh, determining deformation patches included in the projected mesh comprised of deformed mesh elements of the projected mesh that fail deformation criteria, and selecting a cost function to apply to the deformation patches from a set of available cost functions. The curved mesh generation engine 110 may further construct the curved mesh 140 by iteratively adapting the deformation patches based on the selected cost function to obtain adjusted mesh elements and forming the curved mesh 140 as a combination of the adjusted mesh elements and portions of the projected mesh not determined as part of the deformation patches.

These and other deformation-based curved mesh generation features and technical benefits are described in greater detail next.

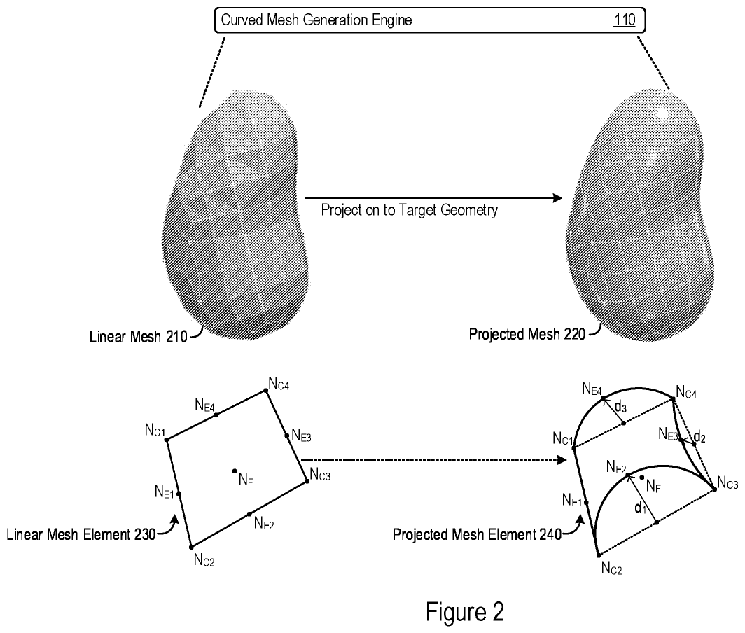

FIG. 2 shows an example generation of a projected mesh and an example determination of a deformed mesh element according to the present disclosure. The features of FIG. 2 are described using the curved mesh generation engine 110 as an example implementation of the described deformation-based curved mesh generation features, though various alternative implementations are contemplated herein as well. In the example of FIG. 2, the curved mesh generation engine 110 projects a linear mesh 210 on to a target geometry to form a projected mesh 220. The projected mesh 220 may include invalid or deformed mesh elements, and the curved mesh generation engine 110 may generate a curved mesh for the linear mesh 210 (and a target geometry) by repairing the invalid mesh elements of the projected mesh 220.

The curved mesh generation engine 110 may generate the projected mesh 220 in various ways and through any viable mesh projection technique in order to project the linear mesh 210 on to a target geometry. In some instances, the linear mesh 210 may be a high-order linear mesh in that mesh elements of the linear mesh 210 include nodes at intermediate points in linear edges, not just at endpoints. The linear mesh 210 accessed by the linear mesh access engine 108 may be a high-order mesh with inserted nodes on mesh element edges (e.g., at midpoints or other selected non-endpoint positions of linear edge segments of mesh elements in the linear mesh 210). In some implementations, the linear mesh access engine 108 or the curved mesh generation engine 110 may itself generate a high-order linear mesh, and may do so by inserting nodes (e.g., high-order Lagrange nodes) on linear edges, faces, or volumes of the linear mesh elements in order to form a high-order linear mesh. In such high-order linear meshes, straight edges of linear mesh elements include one or more intermediate/high-order nodes along the edge itself, which can then be mapped to curved portions of the target geometry.

For high-order linear meshes, the curved mesh generation engine 110 may project the linear mesh 210 to form the projected mesh 220 by fixing the corner nodes (e.g., linear edge endpoint nodes) and projecting high-order nodes (e.g., edge midpoint nodes) onto corresponding CAD curves, shapes, or geometric structure of the target geometry. As such, each given projected mesh element of the projected mesh 220 may correspond to a given linear mesh element of the linear mesh 210 respectively, and the projected mesh elements can have one or more curved edges with high-order nodes of the curved edge projected onto curves of the target geometry. As an example of such a mesh element projection, FIG. 2 shows a linear mesh element 230 of the linear mesh 210 that the curved mesh generation engine 110 may project onto a target geometry to form a corresponding projected mesh element, shown in FIG. 2 as the projected mesh element 240.

Note that in this example shown in FIG. 2, the linear mesh element 230 of the linear mesh 210 is a high-order linear mesh element that includes nodes along non-endpoint portions of linear edge segments. In the specific example shown in FIG. 2, the linear mesh element 230 includes four (4) corner nodes labeled as N_{C1}, N_{C2}, N_{C3}, and N_{C4}, four (4) high-order edge nodes labeled as N_{E1}, N_{E2}, N_{E3}, and N_{E4}, and one (1) face node labeled as N_{F}. The edge nodes N_{E1}, N_{E2}, N_{E3}, and N_{E4} may be high-order nodes, e.g., inserted at midpoints or any other non-endpoint position on the four (4) respective linear edges of the linear mesh element 230.

In projecting the linear mesh element 230 on to a target geometry to form the projected mesh element 240, the edge nodes N_{E1}, N_{E2}, N_{E3}, and N_{E4} may be projected by the curved mesh generation engine 110 onto the curved geometry of a target geometry. For the projected mesh element 240 shown as an example in FIG. 2, the corner nodes N_{C1}, N_{C2}, N_{C3}, and N_{C4} remain in a fixed position that corresponds to the position of the corner nodes N_{C1}, N_{C2}, N_{C3}, and N_{C4} of the linear mesh element 230. However, edge nodes N_{E2}, N_{E3}, and N_{E4} of the projected mesh element 220 have been projected onto curves of a target geometry, and displaced from their original positions in the linear mesh element 230. In particular, the displacement of high-order edge nodes N_{E2}, N_{E3}, and N_{E} is shown in FIG. 2 through the curve displacements d₁, d₂, and d₃ (which can be determined and used in mesh element repair as described in greater detail herein). The curved mesh generation engine 110 may thus generate the projected mesh 220 to map to geometric curves as specified by a target geometry. Accordingly, projected mesh elements of the projected mesh 220 may be curved mesh elements, generated from mapping high-order nodes of corresponding high-order linear mesh elements onto curves of a target geometry.

Note that projection of linear mesh elements of the linear mesh 210 onto a target geometry may form projected mesh elements in a manner that renders at least some of the projected mesh elements as invalid. In the example shown in FIG. 2, the projected mesh element 240 may be invalid since at least one of the nodes of the projected mesh element 240 is no longer within the boundary of the projected mesh element 240. In particular, the face node N_{F} is outside of the perimeter of the projected mesh element 240. Projection of linear mesh elements onto a curved geometry may result in such invalid mesh elements, which be inverted, folded, or tangled in terms of node sequences and locations. Such invalid mesh elements may affect the integrity of FEA analyses, cause simulation errors, and lower the usefulness of curved meshes (at times rendering the entire curved mesh invalid). As such, identifying and correcting invalid mesh elements of a curved mesh may be necessary for proper use of curved meshes.

Validity or invalidity of a mesh element may be specified in various ways, including through deformation criteria. As used herein, deformation criteria may be any criterion used by the curved mesh generation engine 110 to evaluate a mesh element (whether a linear mesh element or curved mesh element). Identification of invalid (also referred to as deformed) mesh elements may thus be controlled by deformation criteria, which can be tuned or configured to flexibly specify degrees of mesh element deformation to be addressed and repaired in curved mesh generation processes. For instance, deformation criteria applied by the curved mesh generation engine 110 may identify each tangled or folded mesh element (e.g., with node positions in an invalid order or location) as deformed, but also identify projected (or curved) mesh elements that differ beyond a certain degree from corresponding linear mesh elements also as deformed mesh elements.

In some implementations, the curved mesh generation engine 110 may apply deformation criteria based on Jacobians computed for mesh elements. In some instances, the curved mesh generation engine 110 may compute a Jacobian as a determinant of a transformation matrix between a given mesh element and a different (e.g. ideal) mesh element. Jacobians may be computed by the curved mesh generation engine 110 for a transformation from a linear mesh element to an ideal element (e.g., ideal triangle, quadrilateral, hexahedron, etc.), from a projected mesh element to an ideal element, from a curved mesh element to an ideal element, from a linear mesh element to a projected or curved mesh element, or in various other combinations.

To determine deformed mesh elements in a mesh (e.g., the projected mesh 220), the curved mesh generation engine 110 may build a mapping from an initial linear mesh with mesh element positions X= [symbol] ^{d×d} to curved mesh with mesh element positions x= [symbol] ^{d×d}, in which d represents a space dimension (e.g., d=1, 2 or 3). The curved mesh generation engine 110 may construct a transformation matrix that maps a given mesh element edge from the initial linear mesh dX to a curved mesh dx, which may also be referred to as a deformation gradient tensor F, in which:

$$F = \frac{dx}{dX} = {∇}_{0} x$$

From this deformation gradient tensor F, it may be understood that FdX=dx. The curved mesh generation engine 110 may compute the determinant of this transformation F as the Jacobian (e.g., between a linear mesh element and a curved mesh element). Put another way, the curved mesh generation engine 110 may compute a Jacobian J as J=detF. The Jacobian J can also be understood as a ratio between the area (or volume) of a curved mesh element dv to the area (or volume) of a corresponding linear mesh element dV. Accordingly, the curved mesh generation engine 110 may alternatively or additionally compute a Jacobian J as follows:

$$J = \frac{dv}{dV}$$

Through Jacobian J computations, the curved mesh generation engine 110 may assess that a negative Jacobian value indicates that the curved mesh element is folded, tangled, or invalid. As such, the curved mesh generation engine 110 may apply deformation criteria that identifies, as deformed mesh elements, any mesh elements with a negative Jacobian J.

Through deformation criteria (e.g., negative Jacobian values), the curved mesh generation engine 110 may identify any curved mesh elements of the projected mesh 220 that are characterized as deformed mesh elements. In that regard, a projected mesh 220 that includes deformed mesh elements may be referred to as an invalid mesh. The curved mesh generation engine 110 may generate output curved meshes by repairing an invalid mesh, such as the projected mesh 220. Mesh element repairs performed by the curved mesh generation engine 110 may include any computations or steps that the curved mesh generation engine 110 takes to address, modify, or adjust deformed mesh elements of an invalid mesh.

For example, the curved mesh generation engine 110 may process the projected mesh 220 until no curved mesh elements fail the deformation criteria (e.g., such that the Jacobian J is positive for every mesh element of the projected mesh 220) or until any other stopping criteria or convergence state is reached. To repair deformed mesh elements, the curved mesh generation engine 110 may adjust node locations of curved mesh elements (e.g., the projected mesh element 240) such that the Jacobian of such curved mesh elements are no longer negative or otherwise no longer fail the deformation criteria. For example, such processing by the curved mesh generation engine 110 for the projected mesh element 240 may involve moving the position of the face node N_{F} and possibly the edge node N_{E1} such that the Jacobian computed for the projected mesh element 240 is no longer negative. While such processing and repair for a single curved mesh element like the projected mesh element 240 may seem relatively simple, the curved mesh generation engine 110 may perform repairs and process node positions of multiple curved mesh elements (e.g., all deformed mesh elements) in parallel to comprehensively process delineated portions of the projected mesh to form a curved mesh without any deformed mesh elements.

Note that the Jacobian J may effectively represent a numerical measurement of a mesh element transformation, e.g., from a linear mesh element to a projected or other curved mesh element. As noted herein, negative Jacobian values may indicate invalid curved mesh elements due to node displacements, folding, tangling, etc. As another example, the deformation criteria applied by the curved mesh generation engine 110 may identify deformed mesh elements with positive Jacobian values that exceed a deformation threshold. Exceeding of a deformation threshold may be any specified variance from an ideal Jacobian value (e.g., a Jacobian value of 1 for ratios). In some implementations, the greater degree to which a Jacobian value for a curved mesh element varies from an ideal value, the greater degree of transformation required to form the curved mesh element from a linear mesh element (or vice versa). In such cases, positive Jacobian values beyond a deformation threshold may indicate a level transformation, distortion, or warping not tolerated for a curved mesh generation process.

The curved mesh generation engine 110 may increase the quality of generated curved meshes and reduced projection distortions by applying deformation criteria that include a deformation threshold for positive Jacobian values. The deformation threshold may specify different variances depending on a direction of variance from the ideal value, which may cover different ratio implementations for a Jacobian J. For example, for positive Jacobian values in the range of 0 to 1 (an ideal value), the deformation threshold may specify a tolerated variance for positive Jacobians less than the ideal value, e.g., any Jacobians with a value equal to or beyond 0.5 less than the ideal value are identified as deformed, in this case Jacobians from [0-0.5). For positive Jacobian values in the range of 1 (ideal value) to −, the deformation threshold may specify a tolerated variance for positive Jacobians greater than the ideal value, e.g., any Jacobians with a value equal to or beyond a value of 24 greater than the ideal value are identified as deformed, in this case Jacobians from 25−∞. Mesh elements with positive Jacobians within the deformation threshold may be identified as valid. While some example forms of deformation thresholds are presented here, any configurable or specified variance from an ideal value is contemplated herein as a suitable deformation threshold.

Through such deformation criteria, the curved mesh generation engine 110 may identify and adjust such deformed mesh elements with positive Jacobian values that exceed the deformation threshold to reduce projection distortions and increase curved mesh quality. In processing such deformed mesh elements, the curved mesh generation engine 110 may adjust node positions of the curved mesh element to adjust its Jacobian values, e.g., until the Jacobian value of the curved mesh element falls below or otherwise satisfies the deformation threshold and is no longer identified as a deformed mesh element by the deformation criteria.

As yet another feature of the deformation-based curved mesh generation technology described herein, the curve mesh generation engine 110 may use regularized Jacobians in certain scenarios. Industrial finite element meshes can be especially complex, and it can be the case that input linear meshes themselves include imperfections that result in negative Jacobian values for linear mesh elements. In such instances, deformation criteria based on a negative Jacobian J may improperly pass over or fail to identify a tangled (or otherwise invalid) curved mesh element that corresponds to linear mesh element that itself includes imperfections. As both the invalid curved mesh element and the imperfect linear mesh element may have negative Jacobian values (e.g., when transformed to an ideal element), then the Jacobian J computed for transforming the imperfect linear mesh element to the invalid curved mesh element may be positive, and may improperly identify a curved mesh element as valid when it should be characterized as deformed due to tangling, folding or other errors.

The curved mesh generation engine 110 may address such situations by identifying and addressing situations in which an input linear mesh includes invalid linear mesh elements. To do so, the curved mesh generation engine 110 may compute a Jacobian value for the linear mesh elements that form a linear mesh (e.g., computing Jacobians for the linear mesh elements of the linear mesh 120 or 210). The curved mesh generation engine 110 may determine a Jacobian for a given linear mesh element of the linear mesh 210 by computing the determinant of a transformation matrix that transforms the given linear mesh element to an ideal element. For any linear mesh element with a negative Jacobian value, the curved mesh generation engine 110 may replace the negative Jacobian j with a regularized Jacobian Jᵣ, which may take the form of a positive Jacobian value applied for a linear mesh element with a computed negative Jacobian value. For linear mesh elements with positive Jacobian values, the regularized Jacobian Jᵣ may be understood simply as the (positive) Jacobian J, and in such cases for valid linear mesh elements, Jᵣ=J. As such, for Jacobian computations for invalid curved mesh elements, use of the regularized Jacobian Jᵣ for an invalid linear mesh element may result in determination of a negative Jacobian value for the invalid curved mesh element (and correctly identify the curved mesh element as deformed).

The curved mesh generation engine 110 may determine a regularized Jacobian Jᵣ for a linear mesh element in various ways. For instance, the curved mesh generation engine 110 may set the regularized Jacobian Jᵣ for a linear mesh element with Jacobian J (determined as a negative value) as follows:

$${J}_{r} = 0.5 ( J + \sqrt{{J}^{2} + 4 {β}^{2}} )$$

In this example, the curved mesh generation engine 110 may set β to be a small quantity, e.g., between 10⁻³ and 10⁻⁴ such that the regularized Jacobian Jᵣ is positive under extreme conditions in which an input linear mesh may include imperfections and invalid linear mesh elements. While the example above includes but one example form of a regularized Jacobian Jᵣ, the curved mesh generation engine 110 may replace a Jacobian J (negative) with any regularized Jacobian Jᵣ (positive) determined in any way for any linear mesh element with a negative Jacobian value.

As described herein, the curved mesh generation engine 110 may generate a projected mesh from a linear mesh and a target geometry, and may further identify deformed mesh elements in the projected mesh based on any number of deformation criteria. In further support of generating a curved mesh, the curved mesh generation engine 110 may process the deformed mesh elements, for example doing so until no curved mesh elements are characterized as deformed according to the deformation criteria. Processing and adjustment of deformed mesh elements of an invalid mesh may allow the curved mesh generation engine 110 to repair an invalid mesh and generate an output curved mesh for an input linear mesh.

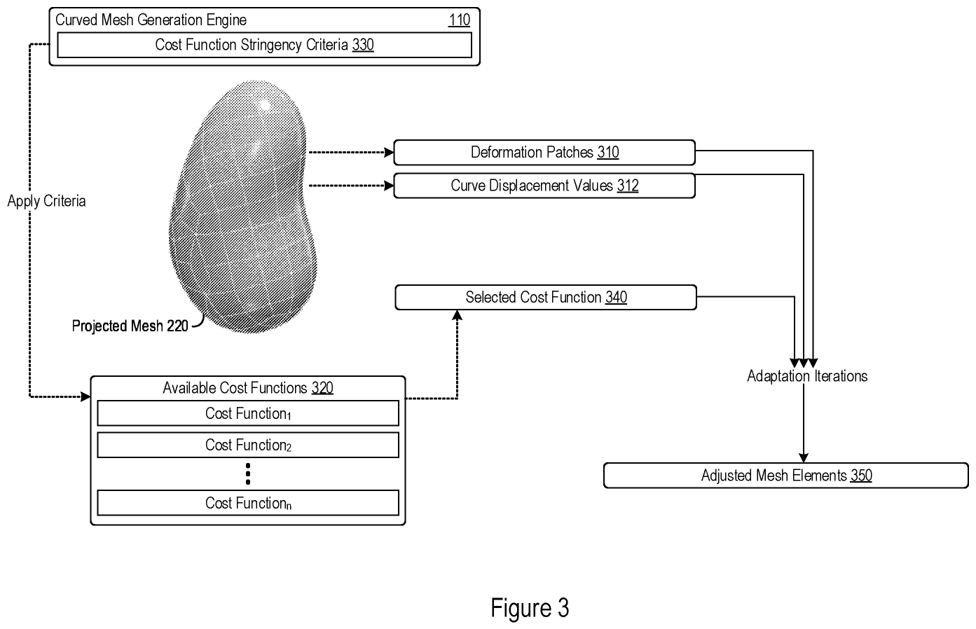

Example features of processing deformed mesh elements according to the present disclosure are described next with reference to FIG. 3.

FIG. 3 shows an example generation of adjusted mesh elements from deformation patches identified for a projected mesh. In the example of FIG. 3, the curved mesh generation engine 110 may process deformed mesh elements identified via deformation criteria, and by doing so support generation of a valid curved mesh for an input linear mesh. In particular, the curved mesh generation engine 110 may do so by repairing the projected mesh 220, which may be an invalid mesh that includes deformed mesh elements caused by projecting the linear mesh 210 to a target geometry. In an invalid mesh (e.g., the projected mesh 220), the curved mesh generation engine 110 may perform multiple adaptation iterations in order to process high-order nodes of deformed mesh elements, and various aspects of such adaptive iterations are described for the deformation-based curved mesh generation technology presented herein.

In repairing deformed mesh elements identified for an invalid mesh (e.g., the projected mesh 220), the curved mesh generation engine 110 need not process each and every curved mesh element of the invalid mesh. In contrast to conventional optimization techniques that process an entire mesh (e.g., all mesh elements of the mesh), the deformation-based curved mesh generation technology presented herein may support processing of a selected subset of the mesh elements of an invalid mesh in order to repair deformed mesh elements. In doing so, the deformation-based curved mesh generation features of the present disclosure may generate curved meshes with valid curved mesh elements with increased performance and speed, as a lesser number of computations (and possibly iterations) are needed to process a lesser number of mesh elements. As such, the deformation-based curved mesh generation technology of the present disclosure may improve the processing speed, memory utilization, and efficiency of computing systems in performing curved mesh generations.

The selected subset of a mesh that the curved mesh generation engine 110 may process to repair deformed mesh elements may be referred to herein as deformation patches. As such, the curved mesh generation engine 110 may determine deformation patches of an invalid mesh to process in order to repair deformed mesh elements. Deformation patches determined by the curve mesh generation engine 110 may include deformed mesh elements of a projected mesh that fail the deformation criteria, e.g., curved mesh elements with negative Jacobian values and/or curved mesh elements with positive Jacobian values that exceed a deformation threshold (e.g., vary beyond a certain degree from an ideal Jacobian value).

In some implementations, the curved mesh generation engine 110 may further include non-deformed curved mesh elements (e.g., that do not fail the deformation criteria) as part of deformation patches as well. For instance, deformation patches determined by the curved mesh generation engine 110 may include non-deformed mesh elements within a threshold distance from deformed mesh elements. As one particular example, the curved mesh generation engine 110 may determine the deformation patches of an invalid mesh to include deformed mesh elements that fail the deformation criteria as well as surrounding mesh elements of the invalid mesh that are direct neighbors of the deformed mesh elements (e.g., any mesh element of a projected mesh that is directly adjacent to, touching, or in direct contact with a deformed mesh element). Any other suitable or configurable distance threshold for determination of deformation patches is contemplated herein.

In the example shown in FIG. 3, the curved mesh generation engine 110 determines the deformation patches 310 for the projected mesh 220, e.g., as including the deformed mesh elements identified for the projected mesh 220 and surrounding mesh elements of the projected mesh that are direct neighbors of the deformed mesh elements. In determining the deformation patches 310, the curved mesh generation engine 110 may also compute curve displacement values 312 for mesh elements included in the deformation patches 310. A curved displacement value may be computed or determined by the curved mesh generation engine 110 as a numerical or vector value (including direction) that specifies a distance between a given node of a curved mesh element and a corresponding node of a linear mesh element of an input linear mesh (e.g., the linear mesh used to generate the projected mesh 220). Examples of curve displacements are shown in FIG. 2 via displacements d₁, d₂, and d₃ of the projected mesh element 240, and the curved mesh generation engine 110 may determine curve displacement values that represent the curve displacements d₁, d₂, and d₃.

In the example of FIG. 3, the curved mesh generation engine 110 may determine curve displacement values 312 for edges (and high order nodes thereof) of the deformed mesh elements resultant from projecting a linear mesh (e.g., the linear mesh 210) on to a target geometry. As described herein, determination of the curve displacement values 312 for mesh elements of the deformation patches 310 may support deformation-based adaptations of the deformation patches 310. Instead of blindly processing the mesh elements of the deformation patches 310, the curved mesh generation engine 110 may pass the curve displacement values 312 as iteration inputs in repairing deformed mesh elements, and such curve displacement values 312 may serve as constraints (e.g., boundary conditions) or otherwise direct the processing of the deformed mesh elements in order to generate adjusted mesh elements that meet deformation criteria.

In processing the deformation patches 310, the curved mesh generation engine 110 may apply a cost function (sometimes referred to as an objective function or energy function). The cost function may be used to numerically assess individual mesh elements, and thus the deformation patches 310 or an entire as well, e.g., as a function of the cost function values of the individual mesh elements of. As the cost function can numerically assess mesh elements of the deformation patches 310, the particular cost function that is used to repair the projected mesh 220 (and, in particular, the deformation patches 310) can greatly impact the quality of an output curved mesh generated and the efficiency at which the output curved mesh is generated.

The deformation-based curved mesh generation technology of the present disclosure may support adaptive cost function selection for the processing of deformation patches to repair deformed mesh elements. Instead of being limited to a single fixed cost function, the curved mesh generation engine 110 may selectively identify a particular cost function from multiple available cost functions to use to process a specific invalid mesh. Such flexibility may allow the curved mesh generation engine 110 to vary applied cost functions to account for mesh characteristics of input linear meshes or corresponding projected meshes. In the example of FIG. 3, the curved mesh generation engine 110 selects a cost function to apply in processing the deformation patches 310 from a set of available cost functions 320. The available cost functions 320 may include any number of different cost functions, which the curved mesh generation engine 110 may store, access, otherwise configure via user input, as predefined defaults, or in various other ways.

The cost functions of the available cost functions 320 used by the curved mesh generation engine 110 may be unique from one another. Different cost functions among the available cost functions 320 may prioritize specific aspects of the mesh repair process. Example aspects that the available cost functions 320 may weight for include minimizing edge, area, or volume distortions (between a processed curved mesh and an input linear mesh), validity guarantees for processed mesh elements (e.g., guaranteeing the Jacobian J of each mesh element is positive), enforcing bijectivity mapping such that straightening a curved mesh will return a valid linear mesh, and more. As an example, the curved mesh generation engine 110 may configure a particular cost function of the available cost functions 320 that measures (e.g., can be used to reduce or minimize) a polyconvex combination of length, area, and volume distortion, a log barrier constraint on a regularized Jacobian Jᵣ, and a bijective distortion (e.g., reducing distortion with respect to inversely mapping a curved mesh to a linear mesh).

An example implementation of such a cost function φ(F) for the transformation matrix/deformation gradient tensor F that the curved mesh generation engine 110 may configure as one of the available cost functions 320 is as follows:

$$φ ( F ) = {μ}_{1} {J}_{r}^{- \frac{2}{3}} ( F : F - 3 ) + {μ}_{2} {J}_{r} ( {F}^{- \frac{\sqrt{3}}{2}} : {F}^{- \frac{\sqrt{3}}{2}} - 3 ) + {{μ}_{3} ( {( {J}_{r} - 1 )}^{2} + log {J}_{r} )}^{2}$$

In this example, μ₁, μ₂, and μ₃ may be weighting parameters that may be configurable or adjusted via tuning or user specification. The term

$${μ}_{1} {J}_{r}^{- \frac{2}{3}} ( F : F - 3 )$$

may serve as a distortion minimizer for shape, the term

$${μ}_{2} {J}_{r} ( {F}^{- \frac{\sqrt{3}}{2}} : {F}^{- \frac{\sqrt{3}}{2}} - 3 )$$

may serve as a bijective distortion minimizer, and the term μ₃((Jᵣ−1)²+log Jᵣ)² may serve as a log barrier to guarantee positive Jacobian values. This example cost function fails in a situation in which an injective map cannot be guaranteed, but yet it can take invalid linear meshes as a starting point (e.g., through use of the regularized Jacobian Jᵣ). While the example cost function above is but one specific example of a cost function supported by the deformation-based curved mesh generation technology of the present disclosure, various other cost functions are contemplated herein, including with varying weighting values or function parameter values, or that account for any number of additional or alternative aspects of processing of invalid curved mesh elements.

As another example, the available cost functions 320 may include one or more cost functions that allow (at least a few) deformed mesh elements to remain in a processed curved mesh. Such an option may be preferred instead of a cost function that fails entirely when repair of an invalid mesh to an end state in which all mesh elements have positive Jacobian values is not possible. Such cost functions may be more relaxed (e.g., less stringent) than the example cost function above, and the curved mesh generation engine 110 may dynamically select such costs functions during runtime. One example of a less stringent cost function that the curved mesh generation engine 110 may include in the available cost functions 320 is as follows:

$$φ ( F ) = {μ}_{1} ( F : F - 3 ) - {μ}_{2} ( {J}_{r} - 1 ) + {{μ}_{3} ( {J}_{r} - 1 )}^{2}$$

Without a log barrier, such a cost function may converge to an output curved mesh solution even when at least some mesh elements still have negative Jacobian values. Such a trade-off between validity guarantees, performance, and mesh quality may be but some of the various factors that the selective cost function features of present disclosure may account for, providing increased flexibility in curved mesh generations. The curved mesh generation engine 110 may include any number or type of cost functions among the available cost functions 320 from which to selectively determine a particular cost function to use to process deformed mesh elements and deformation patches.

The curved mesh generation engine 110 may select a cost function from among the available cost functions 320 to use to process the deformation patches 310 and repair invalid curved mesh elements. To process the deformation patches 310, the curved mesh generation engine 110 may iteratively process the deformation patches 310 such that the cost function is minimized over the entire mesh Ω or over the deformation patches, for example as follows:

$$π ( x ) = {min}_{x} {\int }_{Ω} φ ( F ) d Ω$$

Selection of a cost function may be dictated by cost function stringency criteria 330, which the curved mesh generation engine 110 may set in various ways. The cost function stringency criteria 330 may set a threshold for any evaluation metric by which the curved mesh generation engine 110 assesses cost functions, and may thus be thresholds based on Jacobian values, iteration step sizes, or any other metric that may indicate how many iterations, computations, or resources that will be required for optimization processes to converge to processed curved mesh based on a given cost function.

In some implementations, the curved mesh generation engine 110 may select a cost function from the set of available cost functions 320 through sequential evaluation of the available cost functions 320. For instance, the cost functions may be ordered based on stringency, user sequencing, or according to any other metric, and the curved mesh generation engine 110 may determine sequentially evaluate the available cost functions 320 based on function ordering until a particular cost function that satisfies the cost function stringency criteria 330 is identified. Thus, in operation, the curved mesh generation engine 110 may identify an ordering of the available cost functions 320 and sequentially evaluate the available cost functions 320 according to the ordering and until a given cost function of the available cost functions satisfies cost function stringency criteria 330. The curved mesh generation engine 110 may then determine the given cost function that satisfies the cost function stringency criteria 330 as the selected cost function 340 to apply to the deformation patches 310.

The curved mesh generation engine 110 may sequentially evaluate the available cost functions 320 on a one-by-one basis. For a particular cost function in the one-by-one sequential evaluation, the curved mesh generation may perform an iteration of adapting the deformation patches 310 based on the particular cost function and determine whether the particular cost function satisfies the cost function stringency criteria 330 based on the iteration. For instance, the cost function stringency criteria 330 may be satisfied when the one or more Jacobian values from an iteration do not exceed a threshold Jacobian value, when the step size value for the iteration is not less than a threshold step size value, or a combination of both. As such, the curved mesh generation engine 110 may determine whether the particular cost function satisfies the cost function stringency criteria 330 according to more Jacobian values computed for adapted mesh elements generated from the iteration, a step size value computed for the iteration, or a combination of both.

Accordingly, the curved mesh generation engine 110 may select a cost function from the available cost functions 320. Cost function selection may be performed dynamically during runtime, allowing the curved mesh generation engine 110 to flexibly adapt use of cost functions based on a projected mesh, input linear mesh, optimization process convergence predictions, Jacobian values, and more. As seen in FIG. 3, the curved mesh generation engine 110 determines the selected cost function 340 to apply to the deformation patches 310. Then, the curved mesh generation engine 110 may iteratively adapt the deformation patches 310 based on the selected cost function 340 to obtain adjusted mesh elements 350.

The curved mesh generation engine 110 may apply any type of optimization or processing techniques to minimize the selected cost function 340 for the deformation patches 310 or a curved mesh. In some instances, the curved mesh generation engine 110 may utilize derivative or tangent based optimization processes to adjust nodes of curved mesh elements in the repair process. In a variational framework to discretize the selected cost function 340 using finite elements, the curve mesh generation engine 110 may utilize direction derivatives with respect to virtual and directional displacements that satisfy boundary conditions or other constraints. In some implementations, the curved mesh generation engine 110 utilizes a first Piola-Kirchoff stress tensor and a fourth order Hessian tensor (cost function derivatives). Through a Galerkin technique, an initial domain of the linear mesh and a curved domain of a curved mesh may be represented as isoparametric finite element functions that include a number of nodes in a high-order mesh and an associated basis function for the mesh element. Then, the curved mesh generation engine 110 can then represent discrete systems for the first and second derivatives of the selected cost function 340, through which the curved mesh generation engine 110 can obtain a residual vector and tangent stiffness matrix. These quantities can then be integrated by the curved mesh generation engine 110 at the element level using any quadrature scheme and then assembled (e.g., in parallel) into global sparse linear systems and residual vectors.

As the curved mesh generation engine 110 can thus support computation of first and second derivatives of the selected cost function 340, the curve mesh generation engine 110 may utilize any number of optimizers to support processing of the deformation patches. As one example, the curved mesh generation engine 110 may implement a Newton optimizer with a quadratic line search technique. Through use of a regularized Jacobian Jᵣ, the curved mesh generation engine 110 may guarantee that the tangent stiffness matrix never turns indefinite during adaptation iterations. In some implementations, the curved mesh generation engine 110 may apply a Cholesky factorization for solving the sparse linear system, though may do so following a Hessian filtering technique to numerically guarantee positive definitiveness.

In any of the ways described herein, the curved mesh generation engine 110 may process deformation patches 310 through the selected cost function 340. Optimization processes (e.g., via Newton optimizers) may require iterative processing and evaluation according to the selected cost function 340, and as the curved mesh generation engine 110 may perform multiple adaption iterations to generate the adjusted mesh elements 350. As one example, the curved mesh generation engine 110 may implement the following routine to support and perform the adaptation iterations for a curved mesh including invalid mesh elements (e.g., the projected mesh 220):

Algorithm 1 Deformation-Based Global Optimization Routine

| | |
|---|---|
| 1: | procedure GlobalOptimizer(M) |
| 2: | Extract patches of deformed volume mesh elements P_{V}_{₁} ... P_{V}_{ₖ} |
| 3: | for P_{V}_{ᵢ} in P_{V}_{₁} ... P_{V}_{ₖ} do |
| 4: | Extract surface elements P_{S}_{₁} ... P_{S}_{ₘ}from volume mesh element P_{V}_{ᵢ} |
| 5: | for P_{S}_{ⱼ} in P_{S}_{₁} ... P_{S}_{ₘ} do |
| 6: | Extract curve elements P_{C}_{₁} ... P_{C}_{ₙ} from surface element P_{S}_{ⱼ} |
| 7: | for P_{C}_{ₖ} in P_{C}_{₁} ... P_{C}_{ₙ} do |
| 8: | Compute curve displacement value on curve P_{C}_{ₖ} |
| 9: | end for |
| 10: | Optimize surface mesh on P_{S}_{ⱼ}: LocalOptimizer(P_{S}_{ⱼ}, P_{C}_{₁} ... P_{C}_{ₙ}) |
| 11: | end for |
| 12: | Optimize volume mesh on P_{V}_{ᵢ} : LocalOptimizer(P_{V}_{ᵢ}, P_{S}_{₁} ... P_{S}_{ₘ}) |
| 13: | end for |
| 14: | end procedure |

In this example, the input mesh M may be a curved mesh comprised of 3D mesh elements, such as the projected mesh 220 that includes mesh elements identified as deformed.

The example optimization routine above may include extraction of deformation patches for deformed mesh elements of a higher order (e.g., 3D volume mesh elements). Then, hierarchical extraction of the surrounding 2D surface meshes and 1D curve meshes of the mesh can be performed. Computation of curve displacement values can be performed on the 1D curved meshes (e.g., mesh element edges), and such displacements may result from projection of an input linear mesh on to a target geometry. The computed curve displacement values are then provided as inputs (e.g., constraint inputs) to a local optimization routine for the 2D surface meshes. Upon processing 2D surface mesh elements (e.g., repairing any deformed 2D mesh elements on the surface of the input mesh), the optimization routine may process 3D mesh elements with the repaired 2D surface mesh elements as a constraint (e.g., a fixed boundary condition that cannot change).

As such, the curved mesh generation engine 110 may implement or provide a framework in which multiple dimensions of input meshes can be processed, repaired, and adjusted to repair deformed mesh elements. 2D surface mesh repair may form a constraint by which repair of 3D volume elements are processed. In generating the adjusted mesh elements 350, the curved mesh generation engine 110 may thus determine adjusted surface mesh elements of the adjusted mesh elements 350 based on the cost function, e.g., via any of the optimization and processing techniques described herein. Then, the curved mesh generation engine 110 may determine adjusted volume mesh elements of the adjusted mesh elements 350 using the adjusted surface mesh elements as fixed geometrical elements for determination of the adjusted volume mesh elements.

An example of an optimization routine that the curved mesh generation engine 110 may implement is as follows:

Algorithm 2 Local Newton Optimization Routine with Line Search

| | |
|---|---|
| 1: | procedure LocalOptimizer(P, constraint₁, contraint₂, ...) |
| 2: | Initialize nodal positions X, x₀ = X |
| 3: | tol = 1e⁻⁵, i = 0 |
| 4: | Parallel assembly of initial residual vector R and tangent stiffness K |
| 5: | while norm(R) > tol do |
| 6: | Parallel solve for displacements Kᵤ= −R subjected to constraints |
| 7: | Compute step size α = LineSearch(xᵢ, u, R) |
| 8: | Update positions xᵢ₊₁ = xᵢ + αu |
| 9: | Parallel assembly of residual vector R and tangent stiffness K |
| 10: | i ← i + 1 |
| 11: | end while |
| 12: | end procedure |

In this example, the Linesearch algorithm used to compute iteration step size may be any available line search routine, which the curved mesh generation engine 110 may also utilize in iteration step size determinations in evaluating cost functions via the cost function stringency criteria 330.

In any of the ways described herein, the curved mesh generation engine 110 may iteratively adapt the deformation patches 310 of a curved mesh to generate the adjusted mesh elements 350. The adjusted mesh elements may include repaired mesh elements generated by adjusting node positions of high-order nodes of the deformed mesh elements so that the adjusted mesh elements 350 no longer fail deformation criteria (at least in part, depending on the selected cost function 340). The adjusted mesh elements 350 may thus be repaired versions of deformed mesh elements of the projected mesh 220, and the adjusted mesh elements 350 may be untangled or adjusted to now be valid mesh elements according to the deformation criteria (e.g., having positive Jacobian values within a deformation threshold from an ideal Jacobian value). The curved mesh generation engine 110 may then form an output curved mesh as a combination of the adjusted mesh elements 350 and portions of the projected mesh 220 not determined as part of the deformation patches. This output curved mesh generated by the curved mesh generation engine 110 may be understood as a repaired version of the projected mesh 220 or a high-order curved mesh for the linear mesh 210 without (or with a reduced number of) deformed mesh elements.

While many deformation-based curved mesh generation features have been described herein through illustrative examples presented through various figures, the linear mesh access engine 108 or the curved mesh generation engine 110 may implement any combination of the deformation-based curved mesh generation technology described herein.

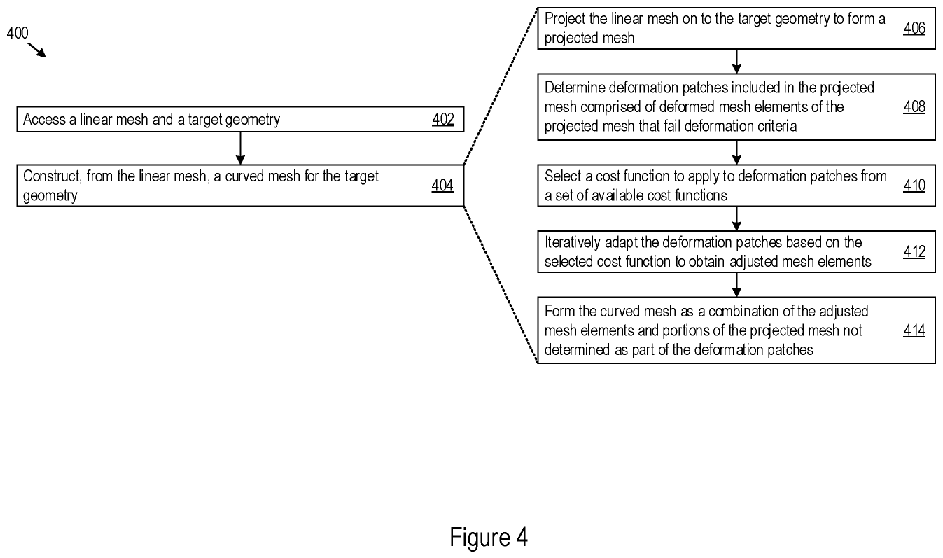

FIG. 4 shows an example of logic 400 that a system may implement to support deformation-based generation of curved meshes. For example, the computing system 100 may implement the logic 400 as hardware, executable instructions stored on a machine-readable medium, or as a combination of both. The computing system 100 may implement the logic 400 via the linear mesh access engine 108 and the curved mesh generation engine 110, through which the computing system 100 may perform or execute the logic 400 as a method to provide any combination of the deformation-based curved mesh generation features presented herein. The following description of the logic 400 is provided using the linear mesh access engine 108 and the curved mesh generation engine 110 as examples. However, various other implementation options by computing systems are possible.

In implementing the logic 400, the linear mesh access engine 108 may access a linear mesh and a target geometry (402), doing so in any of the ways described herein. In implementing the logic 400, the curved mesh generation engine 110 may construct, from the linear mesh, a curved mesh for the target geometry (404). The curved mesh generation engine 110 may do so by projecting the linear mesh on to the target geometry to form a projected mesh (406), determining deformation patches included in the projected mesh comprised of deformed mesh elements of the projected mesh that fail deformation criteria (408), and selecting a cost function to apply to the deformation patches from a set of available cost functions (410). The curved mesh generation engine 110 may further do so by iteratively adapting the deformation patches based on the selected cost function to obtain adjusted mesh elements (412) and forming the curved mesh as a combination of the adjusted mesh elements and portions of the projected mesh not determined as part of the deformation patches (414).

The logic 400 shown in FIG. 4 provides an illustrative example by which a computing system 100 may support deformation-based curved mesh generations according to the present disclosure. Additional or alternative steps in the logic 400 are contemplated herein, including according to any of the various features described herein for the linear mesh access engine 108, the curved mesh generation engine 110, or any combinations thereof.

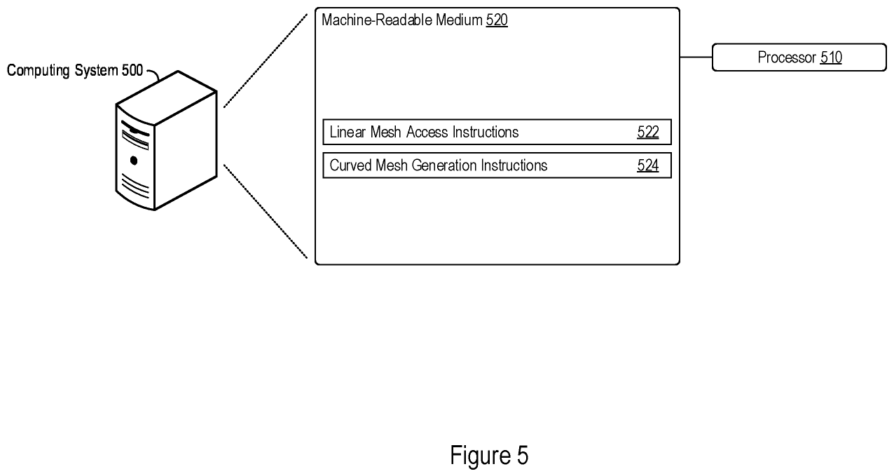

FIG. 5 shows an example of a computing system 500 that supports deformation-based generation of curved meshes. The computing system 500 may include a processor 510, which may take the form of a single or multiple processors. The processor(s) 510 may include a central processing unit (CPU), microprocessor, or any hardware device suitable for executing instructions stored on a machine-readable medium. The computing system 500 may include a machine-readable medium 520. The machine-readable medium 520 may take the form of any non-transitory electronic, magnetic, optical, or other physical storage device that stores executable instructions, such as the linear mesh access instructions 522 and the curved mesh generation instructions 524 shown in FIG. 5. As such, the machine-readable medium 520 may be, for example, Random Access Memory (RAM) such as a dynamic RAM (DRAM), flash memory, spin-transfer torque memory, an Electrically-Erasable Programmable Read-Only Memory (EEPROM), a storage drive, an optical disk, and the like.

The computing system 500 may execute instructions stored on the machine-readable medium 520 through the processor 510. Executing the instructions (e.g., the linear mesh access instructions 522 and/or the curved mesh generation instructions 524) may cause the computing system 500 to perform any aspect of the deformation-based curved mesh generation technology described herein, including according to any of the features of the linear mesh access engine 108, the curved mesh generation engine 110, or combinations of both.

For example, execution of the linear mesh access instructions 522 by the processor 510 may cause the computing system 500 to access a linear mesh and a target geometry. Execution of the curved mesh generation instructions 524 by the processor 510 may cause the computing system 500 to construct, from the linear mesh, a curved mesh for the target geometry. Construction of the curved mesh for the target geometry may include projecting the linear mesh on to the target geometry to form a projected mesh, determining deformation patches included in the projected mesh comprised of deformed mesh elements of the projected mesh that fail deformation criteria, selecting a cost function to apply to the deformation patches from a set of available cost functions, iteratively adapting the deformation patches based on the selected cost function to obtain adjusted mesh elements, and forming the curved mesh as a combination of the adjusted mesh elements and portions of the projected mesh not determined as part of the deformation patches.

Any additional or alternative deformation-based curved mesh generation features as described herein may be implemented via the linear mesh access instructions 522, curved mesh generation instructions 524, or a combination of both.

The systems, methods, devices, and logic described above, including the linear mesh access engine 108 and the curved mesh generation engine 110, may be implemented in many different ways in many different combinations of hardware, logic, circuitry, and executable instructions stored on a machine-readable medium. For example, the linear mesh access engine 108, the curved mesh generation engine 110, or combinations thereof, may include circuitry in a controller, a microprocessor, or an application specific integrated circuit (ASIC), or may be implemented with discrete logic or components, or a combination of other types of analog or digital circuitry, combined on a single integrated circuit or distributed among multiple integrated circuits. A product, such as a computer program product, may include a storage medium and machine-readable instructions stored on the medium, which when executed in an endpoint, computer system, or other device, cause the device to perform operations according to any of the description above, including according to any features of the linear mesh access engine 108, the curved mesh generation engine 110, or combinations thereof.

The processing capability of the systems, devices, and engines described herein, including the linear mesh access engine 108 and the curved mesh generation engine 110, may be distributed among multiple system components, such as among multiple processors and memories, optionally including multiple distributed processing systems or cloud/network elements. Parameters, databases, and other data structures may be separately stored and managed, may be incorporated into a single memory or database, may be logically and physically organized in many different ways, and may be implemented in many ways, including data structures such as linked lists, hash tables, or implicit storage mechanisms. Programs may be parts (e.g., subroutines) of a single program, separate programs, distributed across several memories and processors, or implemented in many different ways, such as in a library (e.g., a shared library).

While various examples have been described above, many more implementations are possible.

1. A method comprising:
by a computing system:
accessing a linear mesh and a target geometry, wherein the linear mesh is comprised of mesh elements with linear edges;
constructing, from the linear mesh, a curved mesh for the target geometry, including by:
projecting the linear mesh on to the target geometry to form a projected mesh;
determining deformation patches included in the projected mesh comprised of deformed mesh elements of the projected mesh that fail deformation criteria;
selecting a cost function to apply to the deformation patches from a set of available cost functions;
iteratively adapting the deformation patches based on the selected cost function to obtain adjusted mesh elements; and
forming the curved mesh as a combination of the adjusted mesh elements and portions of the projected mesh not determined as part of the deformation patches.

2. The method of claim 1, wherein determining the deformation patches comprises determining curve displacement values for edges of the deformed mesh elements resultant from projecting the linear mesh on to the target geometry; and
wherein iteratively adapting the deformation patches comprises applying the curve displacement values as constraints for iterations performed to obtain the adjusted mesh elements.

3. The method of claim 1, comprising determining the deformation patches to include:
the deformed mesh elements; and
surrounding mesh elements of the projected mesh that are direct neighbors of the deformed mesh elements.

4. The method of claim 1, wherein selecting the cost function from the set of available cost functions comprises:
identifying an ordering of the available cost functions;
sequentially evaluating the available cost functions according to the ordering and until a given cost function of the available cost functions satisfies cost function stringency criteria; and
determining the given cost function that satisfies the cost function stringency criteria as the selected cost function to apply to the deformation patches.

5. The method of claim 4, wherein sequentially evaluating the available cost functions comprises, for a particular cost function in the ordering:
performing an iteration of adapting the deformation patches based on the particular cost function; and
determining whether the particular cost function satisfies the cost function stringency criteria based on one or more Jacobian values computed for adapted mesh elements generated from the iteration, a step size value computed for the iteration, or a combination of both.

6. The method of claim 5, wherein the cost function stringency criteria are satisfied when the one or more Jacobian values from the iteration do not exceed a threshold Jacobian value, when the step size value for the iteration is not less than a threshold step size value, or a combination of both.

7. The method of claim 1, wherein iteratively adapting the deformation patches to obtain adjusted mesh elements comprises:
determining adjusted surface mesh elements of the adjusted mesh elements based on the cost function; and
determining adjusted volume mesh elements of the adjusted mesh elements using the adjusted surface mesh elements as fixed geometrical elements for determination of the adjusted volume mesh elements.

8. A system comprising:
a processor; and
a non-transitory machine-readable medium comprising instructions that, when executed by the processor, cause a computing system to:
access a linear mesh and a target geometry, wherein the linear mesh is comprised of mesh elements with linear edges; and
construct, from the linear mesh, a curved mesh for the target geometry, including by:
projecting the linear mesh on to the target geometry to form a projected mesh;
determining deformation patches included in the projected mesh comprised of deformed mesh elements of the projected mesh that fail deformation criteria;
selecting a cost function to apply to the deformation patches from a set of available cost functions;
iteratively adapting the deformation patches based on the selected cost function to obtain adjusted mesh elements; and
forming the curved mesh as a combination of the adjusted mesh elements and portions of the projected mesh not determined as part of the deformation patches.

9. The system of claim 8, wherein the instructions, when executed, cause the computing system to:
determine the deformation patches by determining curve displacement values for edges of the deformed mesh elements resultant from projecting the linear mesh on to the target geometry; and
iteratively adapt the deformation patches by applying the curve displacement values as constraints for iterations performed to obtain the adjusted mesh elements.

10. The system of claim 8, wherein the instructions, when executed, cause the computing system to determine the deformation patches to include:
the deformed mesh elements; and
surrounding mesh elements of the projected mesh that are direct neighbors of the deformed mesh elements.

11. The system of claim 8, wherein the instructions, when executed, cause the computing system to select the cost function from the set of available cost functions by:
identifying an ordering of the available cost functions;
sequentially evaluating the available cost functions according to the ordering and until a given cost function of the available cost functions satisfies cost function stringency criteria; and
determining the given cost function that satisfies the cost function stringency criteria as the selected cost function to apply to the deformation patches.

12. The system of claim 11, wherein the instructions, when executed, cause the computing system to sequentially evaluate the available cost functions by, for a particular cost function in the ordering:
performing an iteration of adapting the deformation patches based on the particular cost function; and
determining whether the particular cost function satisfies the cost function stringency criteria based on one or more Jacobian values computed for adapted mesh elements generated from the iteration, a step size value computed for the iteration, or a combination of both.

13. The system of claim 12, wherein the cost function stringency criteria are satisfied when the one or more Jacobian values from the iteration do not exceed a threshold Jacobian value, when the step size value for the iteration is not less than a threshold step size value, or a combination of both.

14. The system of claim 8, wherein the instructions, when executed, cause the computing system to iteratively adapt the deformation patches to obtain adjusted mesh elements by:
determining adjusted surface mesh elements of the adjusted mesh elements based on the cost function; and
determining adjusted volume mesh elements of the adjusted mesh elements using the adjusted surface mesh elements as fixed geometrical elements for determination of the adjusted volume mesh elements.

15. A non-transitory machine-readable medium comprising instructions that, when executed by a processor, cause a computing system to;
access a linear mesh and a target geometry, wherein the linear mesh is comprised of mesh elements with linear edges;
construct, from the linear mesh, a curved mesh for the target geometry, including by:
projecting the linear mesh on to the target geometry to form a projected mesh;
determining deformation patches included in the projected mesh comprised of deformed mesh elements of the projected mesh that fail deformation criteria;
selecting a cost function to apply to the deformation patches from a set of available cost functions;
iteratively adapting the deformation patches based on the selected cost function to obtain adjusted mesh elements; and
forming curved mesh as a combination of the adjusted mesh elements and portions of the projected mesh not determined as part of the deformation patches.

16. The non-transitory machine-readable medium of claim 15, wherein the instructions, when executed, cause the computing system to:
determine the deformation patches by determining curve displacement values for edges of the deformed mesh elements resultant from projecting the linear mesh on to the target geometry; and
iteratively adapt the deformation patches by applying the curve displacement values as constraints for iterations performed to obtain the adjusted mesh elements.

17. The non-transitory machine-readable medium of claim 15, wherein the instructions, when executed, cause the computing system to determine the deformation patches to include:
the deformed mesh elements; and
surrounding mesh elements of the projected mesh that are direct neighbors of the deformed mesh elements.

18. The non-transitory machine-readable medium of claim 15, wherein the instructions, when executed, cause the computing system to select the cost function from the set of available cost functions by:
identifying an ordering of the available cost functions;
sequentially evaluating the available cost functions according to the ordering and until a given cost function of the available cost functions satisfies cost function stringency criteria; and
determining the given cost function that satisfies the cost function stringency criteria as the selected cost function to apply to the deformation patches.

19. The non-transitory machine-readable medium of claim 18, wherein the instructions, when executed, cause the computing system to sequentially evaluate the available cost functions by, for a particular cost function in the ordering:
performing an iteration of adapting the deformation patches based on the particular cost function; and
determining whether the particular cost function satisfies the cost function stringency criteria based on one or more Jacobian values computed for adapted mesh elements generated from the iteration, a step size value computed for the iteration, or a combination of both, and
wherein the cost function stringency criteria are satisfied when the one or more Jacobian values from the iteration do not exceed a threshold Jacobian value, when the step size value for the iteration is not less than a threshold step size value, or a combination of both.

20. The non-transitory machine-readable medium of claim 15, wherein the instructions, when executed, cause the computing system to iteratively adapt the deformation patches to obtain adjusted mesh elements by:
determining adjusted surface mesh elements of the adjusted mesh elements based on the cost function; and
determining adjusted volume mesh elements of the adjusted mesh elements using the adjusted surface mesh elements as fixed geometrical elements for determination of the adjusted volume mesh elements.
